(19) United States
(12) Patent Application Publication
(10) Pub. No.: US 2026/0173297 A1
(43) Pub. Date: Jun. 18, 2026

(54) MODULAR FIELD DEVICE

(71) Applicant: Endress+Hauser SE+Co. KG, Maulburg (DE)

(72) Inventors: Herbert Schroth, Schopfheim (DE); Bernd Strütt, Steinen (DE); Udo Grittke, Steinen (DE); Daniel Kopp, Lörrach (DE); Martin Kropf, Steinen (DE); Raphael Schonhardt, Rheinfelden (DE)

(21) Appl. No.: 19/129,802

(22) PCT Filed: Oct. 27, 2023
(86) PCT No.: PCT/EP2023/080107

§ 371 Date: May 14, 2025

(30) Foreign Application Priority Data
Nov. 22, 2022 (DE) 10 2022 130 916.9

(51) Int. Cl. H05K 7/14; G01D 11/24; H05K 9/00

(52) U.S. Cl. CPC H05K 7/1462; G01D 11/245; H05K 9/0049

(57) ABSTRACT

A modular field device which, in spite of a plastic housing, fulfills EMC requirements and is easy to manufacture includes a sensor module for determining a process variable. For the purpose of EMC-protection, a conductive enclosure is secured in an inner space of the housing and surrounds a first inner region. A first end region of the enclosure is oriented toward a passageway of the housing. An opposite, second end region of the enclosure is closed by a circuit board such that the inner region is electromagnetically shielded. Accordingly, also the evaluation module connected with the sensor module and serving for communication is EMC protected since it is arranged in the protected inner region on a surface of the circuit board facing the inner region.

The invention relates to a modular field device, which, in spite of nonmetallic housing, fulfills EMC requirements with respect to radiated and electrical conductor bound disturbances and is easy to manufacture.

In process automation technology, field devices are often applied, which serve for registering or for influencing process variables. For registering a process variable, a field device includes, depending on type, particular electronic components for the appropriate measuring principle. Depending on design, the field device type can, thus, be used for measuring, for example, a fill level, a flow, a pressure, a temperature, a pH value and/or a conductivity. The most varied of such field device types are manufactured and sold by the Endress +Hauser group of firms.

Due to the multiplicity of field device types, a modular design is desirable, since it offers a number of advantages both for manufacturing as well as also for the user: On the one hand, by standardizing individual modules, complexity and costs associated therewith are lowered. On the other hand, by standardizing interfaces, a large number of variants can be made with few variants of modules adapting individual field device types to different requirements.

In particular, the electronic components of modular field devices divide into at least two modules. Thus, in a sensor module, the particular measuring principle for registering the process variable is implemented, while an evaluation module converts the analog or digital, raw signal of the sensor module into a standardized analog output signal or digital protocol. Available for this are a number of different industry standards each having its own characteristics, such as, among others, “4 . . . 20 mA”, “HART”, “IO-Link”, “Foundation Fieldbus”, “Profibus”, “ModBus” and “ETHERNET IP”. In general, “module” in the context of the invention means, in principle, a separate arrangement, or encapsulation, of one or more electronic circuits provided for a particular purpose, for example, for measurement signal processing or to serve as an interface. The particular module can, thus, depending on application, comprise one or more corresponding analog circuits for producing, or processing, analog signals. The module can, however, also comprise one or more digital circuits, such as FPGAs, microcontrollers or storage media in cooperating with corresponding programs. In such case, the program is designed to perform the necessary method steps, thus to apply the needed computer operations.

Besides certain electronic modules, also the housing of field devices can be so designed that it can be used for different field device types. For this, the housing must be so designed that, conforming with the sensor module measuring principle, a direct contact with the corresponding process is assured, in order to be able to determine the process variable. Moreover, the housing must provide the modules of a field device type with EMC protection (“Electro Magnetic Compatibility”). I.e., the modules are, on the one hand, to be protected against externally originating, electromagnetic disturbances. On the other hand, potentially disturbing electromagnetic radiation emanating from the modules is also to be blocked. Moreover, it is to be assured that operating heat of the modules is sufficiently drained away. Accordingly, the housing can be made, for example, of metal, such as, for example, stainless steel. In this way, the housing functions as a Faraday cage and is appropriately grounded. Advantageous with a metal housing is its shock, thus impact, resistance, its resistance to solvents and its fire safety In the case of a number of applications, however, a non-metal housing is advantageous, and can even be necessary. Thus, for example, field devices applied in corrosive environments, such as, for instance, ocean-near sites, and in processes involving acidic or alkaline media, preferably use a plastics-based housing. The electronic modules are, in such cases, protected by an additional, electrically conductive enclosure, which turns a corresponding inner region in the inner space of the housing into a Faraday cage for the modules. A corresponding field device is shown, for example, in DE 10 2015 107 306A1 .

However, without extra measures, the electromagnetic shielding and thermal management in the case of non-metal housings with metal enclosure are not as effective as in the case of a metal housing. In such case, the extra measures can in some cases get in the way or contribute to increased production-and developmental costs for the housing.

An object of the invention, therefore, is to provide a modular field device with plastic housing, which is efficiently designed as regards EMC-protection and thermal management and which can be manufactured with little effort.

The object is achieved by a field device for determining a process variable, comprising:
an electrically insulating housing having
   an inner space, and
   a passageway, which adjoins the inner space along a device axis,
an electrically conductive enclosure, which is secured in the inner space and radially surrounds a first inner region of the inner space along a portion of the device axis, having
   a first end region, which is oriented toward the passageway, and
   a second end region, which lies opposite the first end region with reference to the device axis,
a sensor module that is mounted in the passageway of the housing in such a manner that it can register the process variable,
a circuit board, which closes the second end region of the enclosure in such a manner that the inner space is electromagnetically shielded, and
an evaluation module, which is arranged on an inner region facing surface of the circuit board and electrically contacted with the sensor module, in order to transfer the process variable.

In such case, the evaluation module can be designed to meet any industrial communication standards, for example, in order to communicate with superordinated units
according to the digital protocol, “PROFIBUS”, “HART”, “WirelessHART”, “WLAN”, “PROFINET”, “PROFISAFE”, “IO-Link”, “MODBUS TCP”, “MODBUS RTU”, or “ETHERNET/IP”, or
by means of analog signals according to the standard “Namur IEC 60947-5-6”, “4-20 mA” or “0-10 V”.

In principle, the field device of the invention is applicable for measuring any type of process variable. Accordingly, the sensor module can be designed to determine as process variable, for example, a fill level, a temperature, a pressure, a flow, a concentration, for instance a concentration in mol/liter, a conductivity, a viscosity, an acceleration and/or a dielectric constant.

Advantageous in the solution of the invention is that the circuit board contributes to the protection of the modules against electromagnetic disturbance signals and, thus, other measures in this regard can be omitted. To the extent that the circuit board includes an electrical via connected with the evaluation module in the EMC non-protected region of the housing inner space, it is especially advantageous for EMC that there be a high frequency filter tuned for EMC disturbances for attenuating electrical conductor bound disturbances. For this, the high frequency filter can comprise an LC-low-pass filter, especially at least of 2nd order and/or an electrical current compensated choke circuit.

The EMC protection in the inner space can be further increased, when the circuit board includes an essentially complete metal ply. Especially when such metal ply is composed of copper, there results the synergistic effect of simultaneous heat draining from the EMC-protected inner region. This effect is maximized, when the circuit board and the enclosure are designed in such a manner that the metal ply forms at the second end region in the secured state an electrical contact area with a thermal resistance of maximum 15 kelvin/watt, especially less than 5 kelvin/watt. For this, the enclosure at the contact area, and, thus, the second end region can be mechanically processed, for example, milled, in order to remove a possible thermally and electrically poorly conducting casting skin, when the enclosure is made of a stainless steel, a zinc pressure casting, or an aluminum pressure casting. In general, it is in the context of the invention, however, also an option that the enclosure be made of a plastic or a ceramic with, in each case, a conductive coating.

Advantageous for the field device of the invention, is, moreover, that it can be manufactured with little effort. In such case, the method for its manufacture comprises central method steps as follows, wherein the sequence of the steps can vary:
securing the circuit board to the enclosure in such a manner that the evaluation module faces toward the inner region,
securing the sensor module to the passageway and, thus, to the first end region of the enclosure,
connecting the sensor module with the evaluation module, and
securing the enclosure in the inner space of the housing.

The invention will now be explained in greater detail based on the appended drawing, the figures of which show as follows:

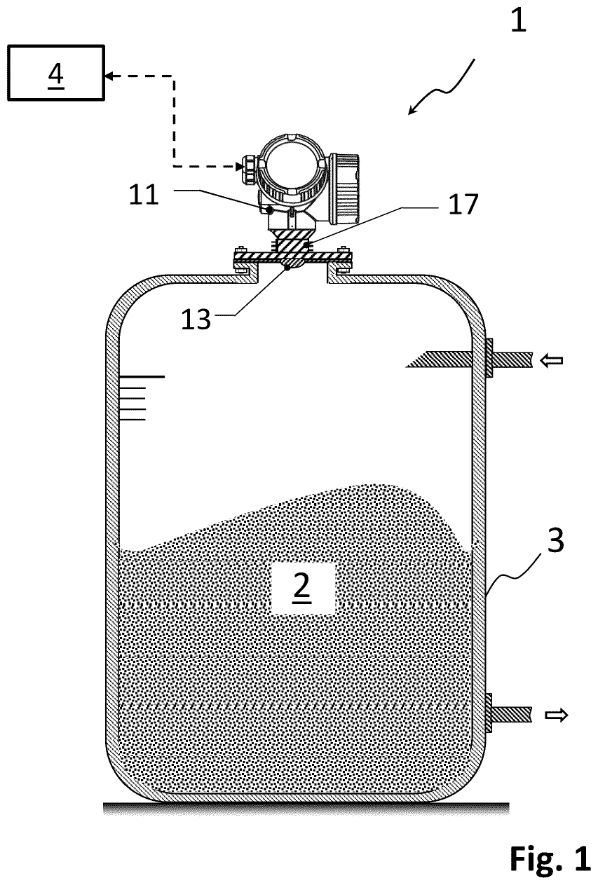

FIG. 1 a field device for determining a process variable in a container,

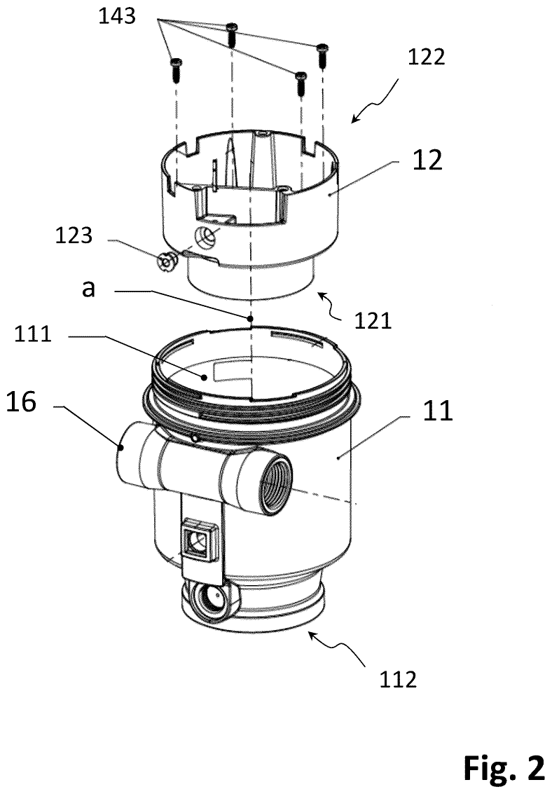

FIG. 2 an exploded view of the field device housing with inner enclosure,

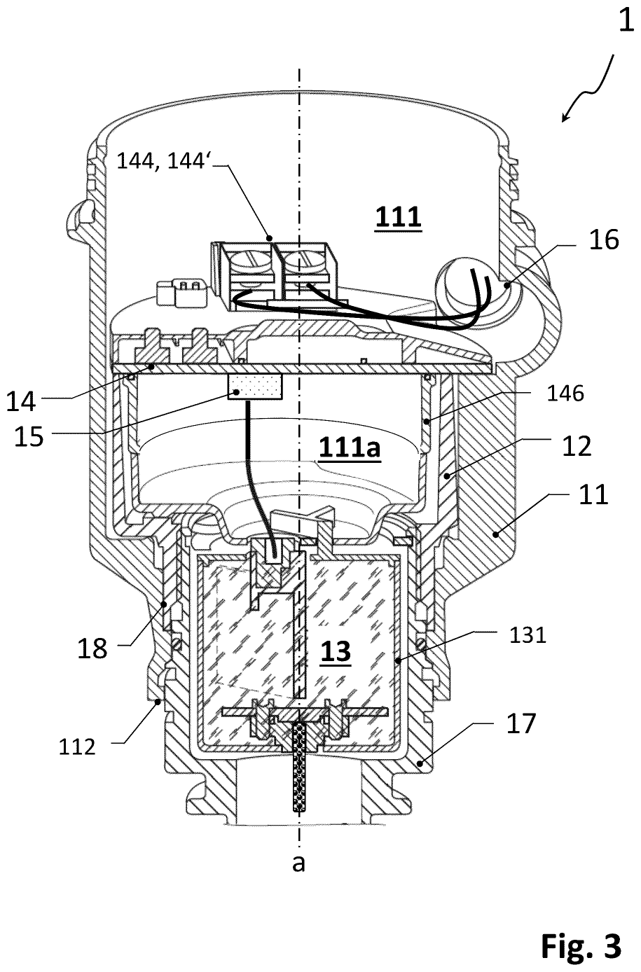

FIG. 3 a sectional view of the field device of the invention, and

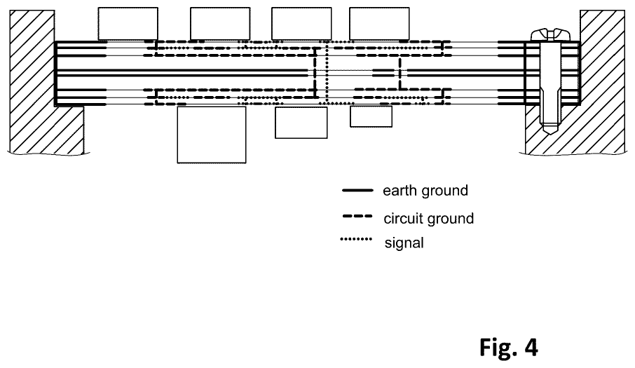

FIG. 4 a detail view of the enclosure in the region of the circuit board.

For an in-principle understanding of the invention, FIG. 1 shows a process container 3 of a process plant serving, for example, for performing chemical or biological reactions, or for storing and dispensing substances 2. In such case, the container 3 can, depending on type of fill substance 2, and, depending on field of application, extend to greater than 100 m high. Depending on the process, to be determined as process variable within the container 3 is, for example, a fill level, a limit level, a temperature, a pH value or a conductivity. In order to be able to determine the particular process variable, a field device 1 having a correspondingly designed sensor module 13 is placed at a defined installed position on the container 3. In this regard, the housing 11 of the field device 1 is secured and oriented via a connection adapter 17 in such a manner at an opening of the container 3 that the sensor module 13 can via a passageway 112 in the housing 11 have access to the container interior and, thus, register the process variable.

In the case of fill level as process variable, the sensor module 13 can operate based, for example, on the FMCW radar principle. For pressure measurement, the sensor module 13 can, in turn, comprise a diaphragm, whose pressure-dependent deflection is registered capacitively or resistively. In order to be able to measure temperature in the container 3 as process variable, it is known, according to the state of the art, to provide the sensor module 13, for example, with a temperature dependent resistance, such as a Pt100 element. Depending on the implemented measuring principle, the sensor module 13 produces the measured value corresponding to the process variable, firstly, as an analog measurement signal, for example, in the form of a direct current, a direct voltage or an alternating voltage signal, which either directly in the sensor module 13 or alternatively in the evaluation module 15 is further processed, for example, amplified, filtered, scaled and/or converted into a digital signal.

Except for the sensor module 13, all additional modules 15 of the field device 1 are arranged completely outside of the container 3 in the housing 11. In such case, the housing 11, for the purpose of corrosion-and weathering resistance, is made of a plastic, such as, for example, ABS, PBT, PEEK or PP. Other than the view in FIG. 1, the field device 1 can, in the case of corresponding design, also be arranged on a pipeline section, in order to measure as process variable, for example, a flow.

As evident from FIGS. 1 and 3, field device 1 is connected via an evaluation module 15 located in the housing 11 to a superordinated unit 4, such as e.g. a local process control system or a decentral server system. Thereby, the field device can 1 by means of a corresponding standard, such as, for instance, “4-20 mA”, “PROFIBUS”, “HART”, “WLAN” or “ETHERNET/IP”, transfer the current measured value of the process variable, for example, in order to control in-and outgoing flows of the container 3. For this, the evaluation module 15 is connected within the field device 1 electrically correspondingly with the sensor module 13. In order to process the measurement signal of the sensor module 13 further, for example, as a result of normalization of the measurement signal with respect to a reference value known by calibration, and/or by value-and time-discretization of the measurement signal, the measured value is preferably converted into a digital value. Depending on design of the sensor module 13, it is possible that the sensor module 13 preprocesses, or conditions, the measurement signal in this regard, at least to a certain degree, before the measured value of the process variable is transferred to the evaluation module 15.

Besides communication of the conditioned measured value of the process variable, also other information concerning general operating state of the field device 1 can additionally be communicated between the superordinated unit 4 and the evaluation module 15. In such case, this means that the data transfer can be designed bidirectionally, such that via the evaluation module 15, in principle, also data, such as, for example, software updates or calibration data, are transferable to the field device 1. The modular design of the evaluation module 15 has the advantage that it can be used in not just one particular field device type.

In order to make the housing 11 of the field device 1 electrically insolating, there is arranged in the inner space 111 of the housing 11 an electrically conductive enclosure 12, which forms a separate inner region 111a protecting against high frequency, electromagnetic, disturbing influences. Enclosure 12 can be made, for example, of a stainless steel, a zinc pressure casting, an aluminum pressure casting or a plastic with a conductive coating. FIG. 2 shows an exploded view of the enclosure 12 and the housing 11 with reference to a device axis a. As indicated, the EMC-protected inner region 111a of the inner space 111 is formed in that the enclosure 12 radially surrounds such along a subsection of the device axis a. As shown, the enclosure 12 encloses two subregions, a circularly round, first end region 121, which faces toward the passageway 112, and a second end region 122 opposite the first end region 121 along the device axis a.

Enclosure 12 is grounded in the example of an embodiment illustrated in FIGS. 2 and 3 via a radially extending grounding clamp 123, which is contactable through a corresponding opening in the housing 11. Alternatively, the enclosure 12, and the modules 13, 15, can be grounded via the cable entrance 16, for example, via a cable shield or a cable protecting, metal tube.

From a manufacturing point of view, enclosure 12 is guided for assembly along the device axis a from an opposite opening of the housing 11 in the direction of the passageway 112 into the inner space 111 and secured there, for example, by means of a plug-in connection. For this, the inner space 111 of the housing 11 has corresponding to the enclosure 12 a basically cylindrical geometry along the device axis a.

In the assembled state, the end region 122 of the enclosure 12 far from the sensor module 13 is closed by a circuit board 14 arranged orthogonally to the device axis a, such as can be seen from the sectional view of the field device 1 in FIG. 3. In such case, the evaluation module 15 is arranged according to the invention on a surface of the circuit board 14 facing the inner region 111a. In this way, enclosure 12 completely EMC protects the evaluation module 15. As indicated in FIG. 2, circuit board 14 can be secured to the enclosure 12 via a screwed connection 143, which in the illustrated example of an embodiment comprises four screws, corresponding internal screw thread in the enclosure 12 and corresponding drilled openings in the circuit board 14.

In the case of the embodiment shown in FIG. 3, evaluation module 15, and the corresponding surface of the circuit board 14, are supplementally encapsulated by a gel-based potting compound, together with a corresponding first potting compound container 146. In such case, also the sensor module 13 is encapsulated in a second potting compound container 131 by means of gel-based potting compound and, in the embodiment shown here, mechanically secured to the first potting compound container 146 of the evaluation module 15 in such a manner that the sensor module 13 is suitably positioned and oriented in the passageway 112 for registering the process variable. Alternatively or supplementally, the sensor module 13 can also be secured to the first end region 121 of the enclosure 12.

Likewise schematically shown in FIG. 3 is the electrical contacting between the sensor module 13 and the evaluation module 15 through the gel-based potting compound. In this way, the measurement signal of the sensor module 13 representing the current measured value of the process variable can be transferred to the evaluation unit 15, in order to be further processed there.

Not explicitly shown in FIG. 3 is that supplementally a mechanical barrier can be provided in the connector-adapter 17 toward the container interior, in order to seal off the field device 1 from the container interior, and vice versa. The barrier is, in such case, in turn, adapted, in each case, for the implemented measuring principle. In the case of radar based fill level measurement, the barrier needs to be transparent for radar signals. In the case of temperature measurement, an effective thermal conductivity is necessary. In the case of pH measurement, the barrier needs to be appropriately ion-conducting, etc.

Since the field device 1 of the views in FIGS. 1 and 3 is secured on the container 3 via the connector-adapter 17, the housing 11 including the components 12, 13, 14, 15 located in the inner space 111 need to be secured to the connector-adapter 17 as stably as possible, for example, by means of an M48-screw thread connection 18. For this, the housing 11 can be provided with a corresponding internal screw thread in the region of the passageway 112. In the illustrated example of an embodiment, connector-adapter 17 is provided for this with a corresponding outer screw thread in its housing-facing end region in the passageway 112 in such a manner that the resulting screw thread connection 18 is oriented along the device axis a.

Alternatively, the internal screw thread of the screw thread connection 18 is not placed in the plastic of the passageway 112, but, instead, provided as a component of the enclosure 12 in the region of the passageway 112. Since the enclosure 12 is, in turn, mechanically secured in the inner space 111 of the housing 11, the housing 11 is, in such case, mechanically connected with the connector-adapter 17 indirectly via the enclosure 12. In this way, the maximum possible number of screw cycles of the screw thread connection 18 is not limited by the plastic of the housing 11. This is noticeable especially when the housing 11 must be periodically screwed off and on, for example, for service-and maintenance tasks. In the two securement variants, the sensor module (13) is so designed that it seals the first end region (121) of the enclosure (12) against high frequency, and, as a result, protects against radiated EMC disturbances. This can be achieved, for example, by making the connector-adapter (17) of metal, such that it can also form an electrical contact for enclosure (12).

As shown in FIG. 3, circuit board 14 comprises, on the surface facing away from the inner region 111a of the enclosure 12, electrical connection terminals 144, 144′ for contacting the evaluation module 15 with the superordinated unit 4 or for energy supply of the field device 1. In such case, the corresponding wiring leading from the housing to the superordinated unit 4 11 passes in the illustrated embodiment through a cable opening 16, to the extent that no wireless transfer protocol is implemented.

For electrical contacting of the connection terminals 144, 144′ with the evaluation unit 15, an electrical via 141 is provided in the circuit board 14. Details of the via 141 are shown in the sectional view of the circuit board 14 in FIG. 4. In accordance therewith, it is shown that the vertical, straight line via 141 correspondingly connects signal leading conductive traces on two surfaces of the circuit board 14 with one another. Corresponding, horizontally extending signal ground traces are likewise connected together using vias.

The evaluation module 15 and the connection terminals 144, 144′are as shown in the embodiment of the circuit board 14 in FIG. 4 not directly connected together by vias 141, but, instead, supplementally via high frequency filters 161, 162, 163, 164. This serves to filter out possible high frequency, electromagnetic disturbing radiation, in order to give EMC protecton to the inner region 111a. In such case, the high frequency filters 161, 162, 163, 164 need to be transmissive for those frequencies, at which the transmission standard works. Since the sending frequencies in the case of “HART”, “Profibus” and comparable industrial transmission standards lie below 10 kHz, it is in the context of the invention, consequently, advantageous, that the high frequency filters 161, 162, 163, 164 be constructed as lowpass filters. In order to achieve an effective edge steepness of at least 12 dB per octave, it is further advantageous, that the high frequency filters 161, 162, 163, 164 comprise at least one lowpass filter of second order. Not shown in FIG. 4 is that the high frequency filters 161, 162, 163, 164 can optionally be electrical current compensated chokes (better known as “common mode choke”), in order to suppress common mode disturbance signals, which can, in given cases, enter via which connection terminals 144, 144′.

In the case of the example of an embodiment shown in FIG. 4, the high frequency filters 161, 162, 163, 164 are designed as LC-lowpass filters of fourth order. In such case, a first capacitance 161 and a first inductance 163 of the LC-lowpass filter are arranged on that surface of the circuit board 14, which faces away from the inner region 111a of the enclosure 12. Arranged on the opposite surfave of the circuit board 4, which faces the inner region 111a, are a second capacitor 162 and a second inductance 164 of the LC-lowpass filter. It is, accordingly, within the scope of the invention not fixedly prescribed, on which surface of the circuit board 14 the high frequency filter 161, 162, 163, 164 is arranged. In such case, the components of the high frequency filters 161, 162, 163, 164 can be, for example, SMD components. Alternatively to an arrangement on a circuit board surface, the components 161, 162, 163, 164 can, alternatively, also be embedded in the circuit board 12.

The EMC-protective action is further increased, when, as shown in FIG. 4, circuit board 14 comprises a separate copper ply 142, which, with exception of openings for vias 141, is complete. In such case, this function can, in principle, also be achieved by using another metal instead of copper, such as, for example, gold. Since in the case of metals with good electrical conductivity usually also a good thermal conductivity is present, the synergistic effect is achieved that the copper ply 142 can, in such case, serve at the same time for removing heat from components arranged on the circuit board 14. For this, the circuit board 14 and the enclosure 12 are to be constructed in such a manner that the copper ply 142 forms at the second end region 122 in the secured state not only an electrical connection to the enclosure 12, but also the circuit board 14 is grounded and, as a result, shields disturbing radiation and electrical line bound disturbances are removed. In such case, signal ground plies and the copper ply 142 are in the example of FIG. 4 connected together via an electrical capacitance, in order to drain electrical conductor bound disturbances, without interfering with the galvanic isolation.

Advantageously, the copper ply 142 and the enclosure 12 form with one another an effective thermal contact area of low thermal resistance of about 4 kelvin/watt. In this regard, the copper ply 142, can, moreover, be so embodied that it expands in the circuit board 14 in a defined lateral region surrounding the screwed connection 143 to a plurality, or even all plies of the circuit board, such as is shown in FIG. 4.

### LIST OF REFERENCE CHARACTERS

1 field device
2 fill substance
3 container
4 superordinated unit
11 housing
12 enclosure
13 sensor module
14 circuit board
15 evaluation module
16 cable opening
17 connector-adapter
18 screw thread connection
111 inner space of the housing
111a inner region
112 passageway
121 first end region
122 second end region
123 grounding connection
131 second potting compound container
141 electrical via
142 metal ply
143 screwed connection
144, 144′ connections
145 isolating ply
146 first potting compound container
147 capacitance
161, 162 capacitors of the high frequency filters
163, 164 inductances of the high frequency filters
a device axis

1-9. (canceled)

10. A field device for determining a process variable, comprising:
an electrically insulating housing having an inner space and a passageway that adjoins the inner space along a device axis;
an electrically conductive enclosure that is secured in the inner space and radially surrounds a first inner region of the inner space along a portion of the device axis, wherein the electrically conductive enclosure includes a first end region that is oriented toward the passageway and a second end region that lies opposite the first end region with reference to the device axis;
a sensor module that is mounted in the passageway in such a manner that it can register the process variable;
a circuit board that closes the second end region of the enclosure in such a manner that the first inner region is electromagnetically shielded; and
an evaluation module that is arranged in the first inner region facing surface of the circuit board and that is electrically contacted with the sensor module to transfer the process variable.

11. The field device as claimed in claim 10, wherein the circuit board includes an electrical via connected with the evaluation module, and wherein a high frequency filter is connected to the via.

12. The field device as claimed in claim 11, wherein the high frequency filter includes an LC-low-pass filter and/or an electrical current compensated choke circuit.

13. The field device as claimed in claim 11, wherein the circuit board includes a predominantly complete metal ply.

14. The field device as claimed in claim 13, wherein the circuit board and the enclosure are designed such that the metal ply forms, at the second end region in the secured state, an electrical contact area with a thermal resistance of maximum 15 kelvin/watt.

15. The field device as claimed in claim 10, wherein the evaluation module is designed to communicate with a superordinated unit according to a digital protocol “PROFIBUS”, “HART”, “WirelessHART”, “WLAN”, “PROFINET”, “PROFISAFE”, “IO-Link”, “MODBUS TCP”, “MODBUS RTU”, or “ETHERNET/IP”, or via analog signals according to the standards “Namur IEC 60947-5-6”, “4-20 mA”, or “0-10 V”.

16. The field device as claimed in claim 10, wherein the sensor module is designed to determine as the process variable a fill level, a temperature, a pressure, a flow, a concentration, a conductivity, a viscosity, an acceleration, and/or a dielectric constant.

17. The field device as claimed in claim 10, wherein the electrically conductive enclosure is made of a stainless steel, a zinc pressure casting, an aluminum pressure casting, or a plastic with a conductive coating.

18. A method for producing a field device, the method comprising:
providing:
an electrically insulating housing having an inner space and a passageway that adjoins the inner space along a device axis;
an electrically conductive enclosure having a first end region that is oriented toward the passageway and a second end region that lies opposite the first end region with reference to the device axis;
a sensor module;
a circuit board; and
an evaluation module;
securing the circuit board to the electrically conductive enclosure such that the evaluation module faces toward an interior of the electrically conductive enclosure;
securing the sensor module to the passageway and thus to the first end region of the electrically conductive enclosure;
connecting the sensor module with the evaluation module; and
securing the electrically conductive enclosure in the inner space of the electrically insulating housing.
